(19) United States
(12) Patent Application Publication
(10) Pub. No.: US 2011/0234240 A1
(43) Pub. Date: Sep. 29, 2011

(54) MONITORING DEHYDRATION USING RF DIELECTRIC RESONATOR OSCILLATOR

(75) Inventor: Thomas A. Yager, Encinitas, CA (US)

(73) Assignee: Empire Technology Development, LLC, Wilmington, DE (US)

(21) Appl. No.: 12/729,364

(22) Filed: Mar. 23, 2010

(51) Int. Cl. G01R 27/04

(52) U.S. Cl. 324/634

(57) ABSTRACT

Technologies are generally described for monitoring dehydration levels of a subject using Radio Frequency (RF) dielectric resonant oscillators (DROs) that may be affixed to the skin of the subject. According to some example aspects, a sensor comprising a microstrip ring resonator may be affixed to the skin and used to determine the change in hydration of a person quantitatively and/or qualitatively. An RF emitter can be configured to emit a scanning signal to the sensor, where the scanning signal can be swept over a specified frequency range. The sensor is configured to resonate in response to the scanning signal, where characteristics of the sensor's resonance (e.g., the specific frequency and “Q” factor of the resonance) is impacted by dielectric losses of the sensor to the skin due to hydration level of the subject.

### BACKGROUND

Unless otherwise indicated herein, the materials described in this section are not prior art to the claims in this application and are not admitted to be prior art by inclusion in this section.

Dehydration can be defined as excessive loss of body fluid. In physiological terms, dehydration may entail a deficiency of fluid within an organism. Dehydration may be caused by losing too much fluid, not drinking enough water or fluids, or both. There are three main types of dehydration: hypotonic (primarily a loss of electrolytes, sodium in particular), hypertonic (primarily a loss of water), and isotonic (equal loss of water and electrolytes). While the most commonly seen type of dehydration in humans is isotonic dehydration, distinction of isotonic from hypotonic or hypertonic dehydration may be important when treating people who become dehydrated.

Vomiting, diarrhea, and excessive perspiration without sufficient liquid intake are some of the common causes of dehydration, which may be particularly worrisome for athletes and people that work under hot and dry conditions. Dehydration may cause rapid heartbeat, low blood pressure, heat exhaustion, kidney stones, or shock. Severe dehydration may result in seizures, permanent brain damage, or death. A person may be near severe dehydration before common symptoms such as thirst or dry mouth are apparent. Methods for directly determining dehydration typically require laboratory tests (blood chemistry, urine specific gravity, etc.).

### BRIEF DESCRIPTION OF THE DRAWINGS

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 illustrates top and side views of an example dehydration monitoring device using a Radio Frequency “RF” dielectric resonator oscillator “DRO”;

FIG. 2 illustrates an example system for using an RF DRO based dehydration monitoring device;

FIG. 3 illustrates example systems for data collection and control of an RF DRO based dehydration monitoring device;

FIG. 4 illustrates example placements of an RF DRO based dehydration monitoring device on a human body;

FIG. 5 includes a diagram of quality factor determination based on a frequency curve of a resonator and a diagram of a moisture vs. quality factor graph illustrating how characteristics of an RF DRO may be utilized in an RF resonator based dehydration monitoring device;

FIG. 6 illustrates a general purpose computing device, which may be used to control an RF DRO based dehydration monitoring device;

FIG. 7 illustrates a networked environment, where a system for dehydration monitoring using an RF DRO may be implemented; and

FIG. 8 illustrates a block diagram of an example computer program product; all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatus, systems, devices, and/or computer program products related to monitoring dehydration levels using a Radio Frequency dielectric resonator oscillator attached to skin.

Briefly stated, dehydration levels of a subject may be monitored using Radio Frequency (RF) dielectric resonant oscillators (DROs) that may be affixed to the skin of the subject. According to some example aspects, a sensor comprising a microstrip ring resonator may be affixed to the skin and used to determine the change in hydration of a person quantitatively and/or qualitatively. An RF emitter can be configured to emit a scanning signal to the sensor, where the scanning signal can be swept over a specified frequency range. The sensor is configured to resonate in response to the scanning signal, where characteristics of the sensor's resonance (e.g., the specific frequency and “Q” factor of the resonance) is impacted by the dielectric constant and dielectric losses of the sensor to the skin due to hydration level of the subject.

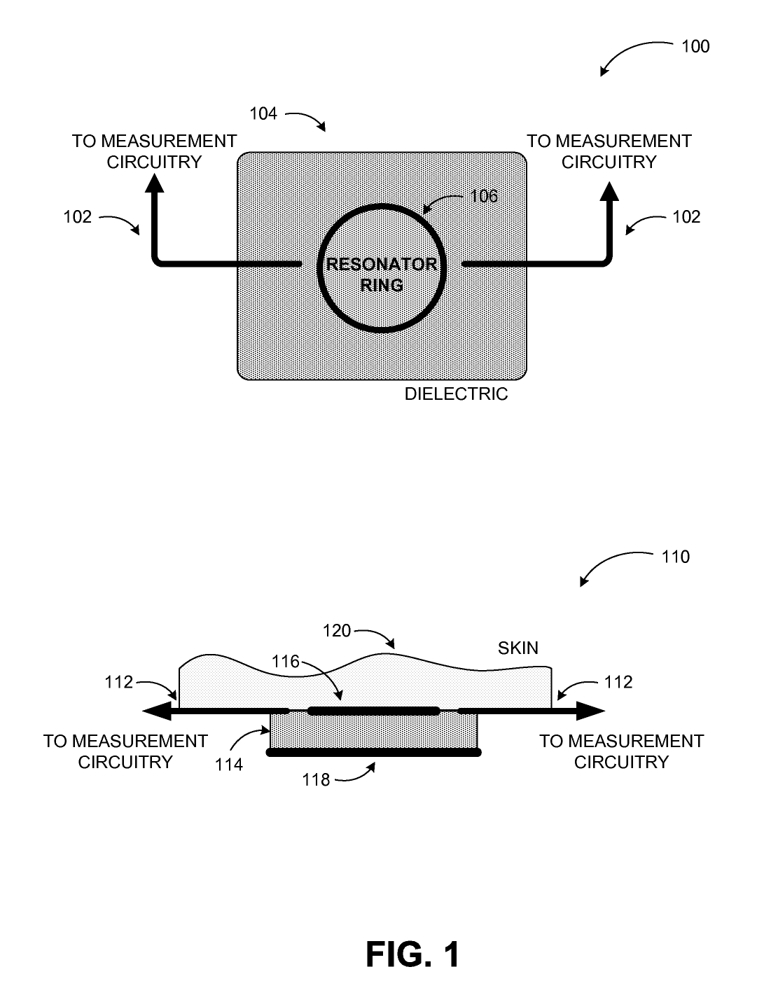

FIG. 1 illustrates top and side views of an example dehydration monitoring device using an RF DRO that is arranged in accordance with at least some embodiments described herein. The top view of the dehydration monitoring device is illustrated as device 100 in FIG. 1, while the side view is illustrated as device 110 of FIG. 1.

As illustrated by device 100, an example microstrip ring resonator 106 (hereinafter simply referred to as a “resonator) can be constructed as a simple transmission line resonator whose geometry may be as shown. The resonator 106 can be excited by an RF signal that can be capacitively coupled to the resonator via a transmission line 102. Based on the electrical length of the resonator 106, a standing wave pattern may be achieved at select frequencies (resonant frequencies) around the circular path of the resonator 106. For the resonant frequencies of resonator 106, the wavelength (λ) can be described as a function of the diameter of the ring:

$$λ = \frac{π d}{N} , \qquad [ 1 ]$$

where d is the diameter and N is an integer.

At resonant frequencies, a voltage maximum occurs at the excitation point. By placing the capacitively coupled transmission line 102 at the voltage maximum point, the electromagnetic field in the resonator 106 may be probed through direct contact measurement to detect the resonant frequencies. Spectral measurement may also reveal the quality factor, Q, of the resonator 106, which is an indication of power loss in the resonator 106.

Quality factor, Q, is a dimensionless parameter that can be utilized to describe and characterize a resonator's performance in terms of bandwidth relative to center frequency. Higher Q values indicate a lower rate of energy loss relative to the stored energy of the oscillator. Sinusoidally driven resonators with higher Q factors tend to resonate with greater amplitudes at the resonant frequency of the resonator, but the resonator may have a fairly small range of frequencies for which resonance can be achieved. The range of frequencies for which the resonator resonates can be referred to as the bandwidth of the resonator. Thus, high Q resonators resonate with a smaller range of frequencies and are more stable. Generally, Q is defined in terms of the ratio of energy stored in the resonator to that of the energy being lost in one cycle:

$$Q = 2 π \frac{Stored Energy}{Dissipated Energy ( per cycle )} . \qquad [ 2 ]$$

The definition of Q can be rewritten in terms of the ratio of the energy stored to that of the energy dissipated per cycle as:

$$Q = ω \frac{Stored Energy}{Power Loss} , \qquad [ 3 ]$$

where ω is the angular frequency.
Another definition for Q may be expressed as a ratio of resonance (or center) frequency f₀ of the resonator to the bandwidth, Δf:

$$Q = \frac{{f}_{0}}{Δ f} . \qquad [ 4 ]$$

In practice, the microstrip ring resonator 106 and the transmission lines 102 can be formed on dielectric substrate 104. The dissipated power in the resonator includes dielectric loss, conductor loss, and/or radiation loss. The dielectric loss, as well as the quality factor, is dependent on the dielectric characteristics of the dielectric substrate 104. Thus, attaching the microstrip ring resonator 106 (and the transmission lines 102) to a moisture containing substance such as human skin 120 and the region below the skin, as shown in diagram 110, may affect the overall dielectric characteristics for the resonator resulting in a moisture dependent dielectric constant and quality factor for the resonator.

Device 110 of FIG. 1 illustrates a side view of an example resonator, where one side (e.g., bottom) of the microstrip ring resonator 116 and transmission lines 112 are affixed to a dielectric substrate 114, and the other sides are affixed to skin 120. Optionally, a conductive ground plane 118 may be placed on the dielectric substrate 114 opposite from the microstrip ring resonator 116. In a system that is configured in accordance with at least some embodiments described herein, transmission lines 102 and 112 shown in devices 100 and 110, respectively, may be configured to provide the measurement signals to a measurement circuit (not shown) in addition to providing the excitation signal to the resonator.

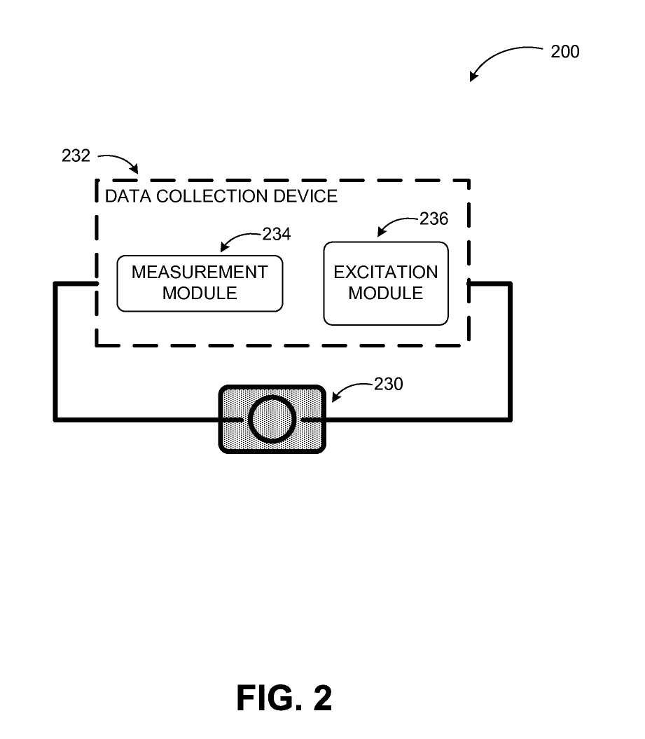

FIG. 2 illustrates an example system for using an RF DRO based dehydration monitoring device that is arranged in accordance with at least some embodiments described herein. The example system shown in diagram 200 includes functional components for a measurement module 234, an excitation module 236, and a sensor 230. The sensor 230 may include a microstrip ring resonator, one or more transmission lines, and a dielectric substrate as previously discussed above with respect to FIG. 1. In some examples the measurement module 234 and the excitation module 236 may be implemented as separate modules. In some other examples, the measurement module 234 and the excitation module 236 may be configured as part of a self contained control and data collection device 232, a general purpose computing device, or part of separate devices.

In some examples, the sensor 230 may be implemented as a double sided flexible circuit (e.g., polyimide dielectric and metallization). The bottom side of an example flexible circuit may be a ground plane, while a top side of the example flexible circuit may include the microstrip ring resonator with microstrip leads on either side. The topside metal layers may be coated with a durable metal material such as gold and/or a thin conformal coating that may be added for environmental protection. Electrical connection to the microstrip leads may be achieved through coaxial cables or similar materials configured to couple the sensor 230 to the excitation and measurement modules.

As discussed previously, characteristics of the microstrip ring resonator can be determined, in part, by the dielectric constant of the dielectric substrate and characteristics (e.g., moisture content) of body fluids beneath the skin and regions below the skin, to which the sensor 230 is affixed. At low frequencies (e.g. less than about 100 MHz), the relative permittivity is dominated by the high capacitance of cell membranes and relative conductivity is dominated by ions in the blood plasma. At high frequencies (e.g. between about 100 MHz and about 250 GHz), the cell membranes may act as an electrical short circuit and conductivity of the cell membranes may be dominated by excitation and relaxation of water molecules. Thus, the more water in the body (hydration), the greater the high frequency conductivity of the tissue (e.g. skin).

The quality factor of the DRO is approximately inversely proportional to the high frequency dielectric conductivity. In other words, as moisture of the body fluids increases, the quality factor of the DRO decreases. In a system according to embodiments, dehydration level of the body may be determined quantitatively by measuring moisture content of the body fluids beneath just under the skin. The moisture measurement may be accomplished by changing the frequency of an excitation signal through the resonance of the microstrip ring resonator and determining the quality factor as discussed previously.

According to further embodiments, a qualitative measurement may be made by measuring high frequency conductivity (complex permittivity) or dielectric loss. Alternatively, relative dehydration may be monitored over time by determining a change in conductivity (or dielectric loss) of the skin relative to the initial conductivity (dielectric loss) of the skin.

Since the methods described herein may be relatively more effective at higher frequencies and a size of the microstrip resonator ring may have other practical limitations (e.g., it needs to be affixed to the body), the frequency range (and thereby the resonator size) may be selected for operation in the microwave range of frequencies. For example, for a frequency of 2.4 GHz and a skin dielectric constant of 40, an approximate ring diameter is 1.3 cm. A sensor implemented with such a ring may be easily placed over the arm, on the leg, or similar places on the body. Of course, other frequencies and resonator sizes may also be used in implementing a system according to at least some embodiments described herein.

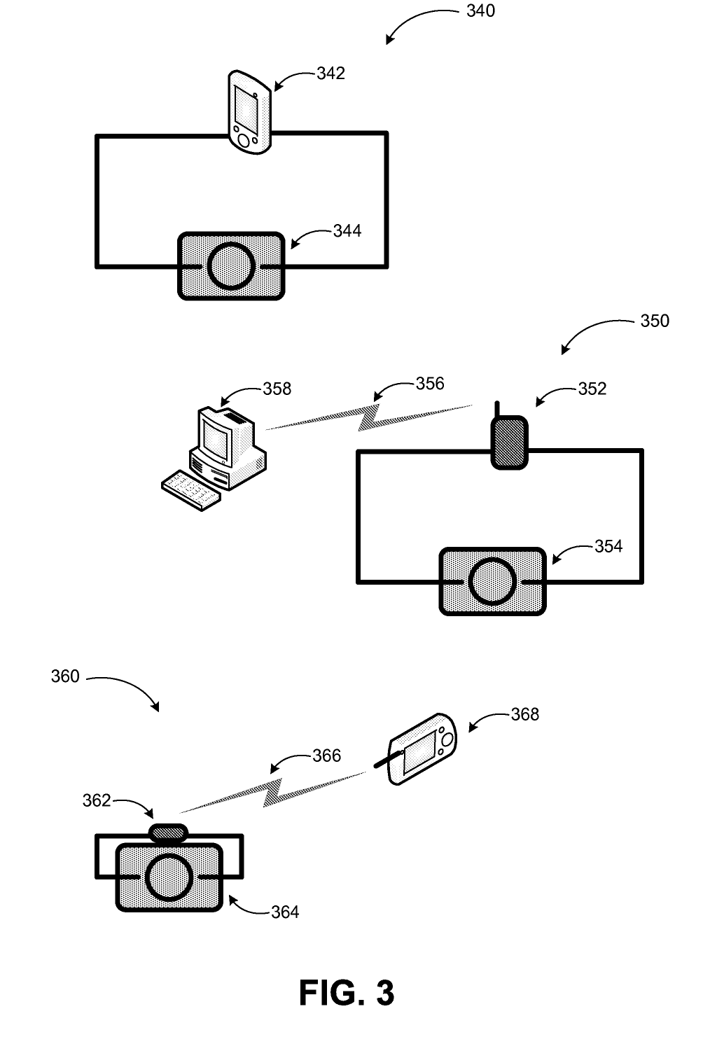

FIG. 3 illustrates some example systems for data collection and control of an RF DRO based dehydration monitoring device that is configured in accordance with at least some examples described herein. Dehydration level monitoring through an RF DRO placed on the skin may be implemented through a variety of systems. The sensor and associated excitation/measurement modules may be implemented as a self contained device that may be configured to store and/or transmit data to remote computing devices, as a multi-component device that may electrically or wirelessly coupled to remote computing devices, or the sensor may be coupled directly to a general purpose/specialized computing device that may configured to perform the tasks of the excitation/measurement modules.

Diagram 360 is an example of a first configuration including a sensor 364 and an excitation/measurement module 362. Sensor 364 includes a microstrip ring resonator, transmission lines, and a dielectric substrate. Sensor 364 is electrically coupled to the excitation/measurement modules 362, which may together be considered a single device. In addition to determining dehydration levels by being placed on the skin, the device may be configured to communicate wirelessly with a remote computing device 368 to provide determined dehydration levels thereto. Alternatively, the device may be configured to store the determined dehydration levels as data to be downloaded subsequently.

Diagram 350 is an example of a second configuration including a sensor 354 and an excitation/measurement module that is housed in a separate component 352. Sensor 354 is electrically coupled to the separate component 352. Separate component 352 may be configured to communicate with computing device 358 through a wireless communication 356 or through an electrical connection, and may be configured to provide measurement results and/or receive control parameters such as one or more of a frequency range to be scanned, a level of an excitation signal to be applied, or some other similar parameters. According to an example implementation, sensor 354 may be coupled to separate component 352 through a flexible strap such that the sensor can be placed on an arm, leg, or torso with the separate component located on an opposite side of the flexible strap.

Diagram 340 is an example of the third configuration including a sensor 334 and a handheld computing device 342. Handheld computing device 342 may include a measurement module and an excitation module (e.g., in form of plug-in modules), which may be coupled to the sensor 344. The handheld computing device 242 may be configured to monitor dehydration levels by providing an excitation signal (e.g., microwave) to the resonator of the sensor 344 and measuring quality factor or dielectric loss of the resonator by scanning frequencies as described herein.

The example systems discussed above may perform additional tasks such as formatting, analysis, and reporting of the collected dehydration data. According to some embodiments, an alarm mechanism may be set such that upon determining dehydration levels in excess of a predefined threshold, the system may alert the person using the system, a healthcare provider, or another designated person. Furthermore, determined dehydration levels may be displayed on the system, at a remote location, or output to a designated target such as a printer.

Each of the computing devices such as computing device 342, 358, or 368 may be a general purpose computing device or a special purpose computing device that may be comprised as a standalone computer, a networked computer system, a general purpose processing unit (e.g., a micro-processor, a micro-controller, a digital signal processor or DSP, etc.), a special purpose processing unit (e.g., an specialized controller, or similar devices). The presently described dehydration level measurement system is not limited to humans or animals, and may also include inanimate objects (e.g., fruits, vegetables, paper, grain, etc.).

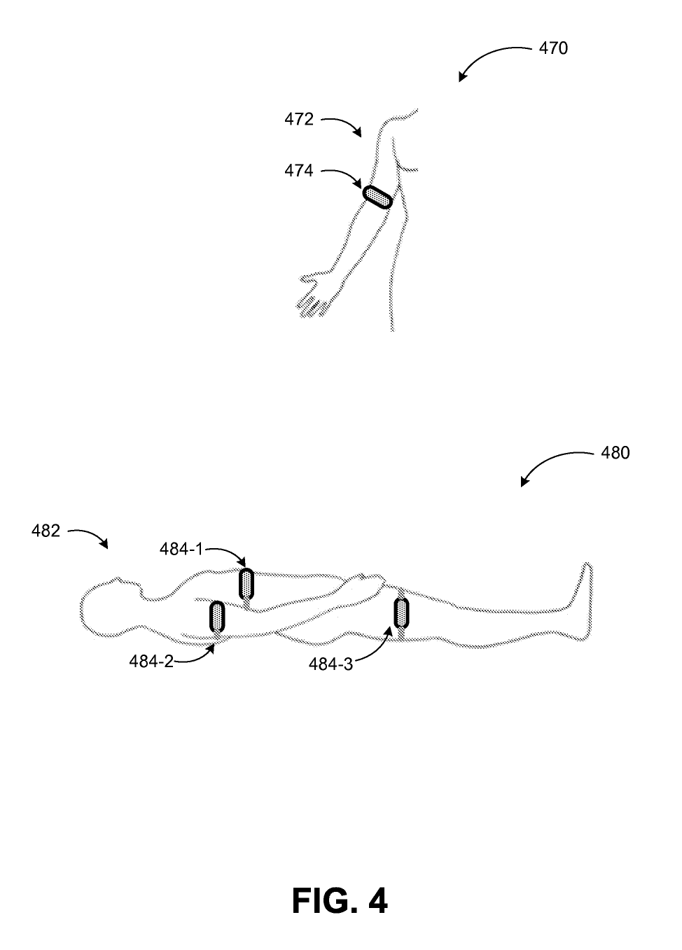

FIG. 4 illustrates example placements of an RF DRO based dehydration monitoring device on human body, in accordance with at least some examples described herein. Diagram 470 illustrates a sensor 474 of a dehydration monitoring system strapped on to an arm 472 with the sensor being placed on the inside of the arm 472 just below the arm pit. This region of the human body has a smaller change in the dilation/constriction of peripheral blood vessels, which the body uses for temperature regulation. Flow of blood through the peripheral blood vessels is an indication of level of body hydration among other things. The system electronics may be mounted on the outer part of the arm.

Diagram 480 illustrates three example locations for the sensor of a dehydration monitoring system (484-1, 484-2, 484-3) on the arm, on the leg, and on the torso of body 482. As mentioned before, a sensor of a dehydration monitoring system may be placed in other suitable locations on the body as well. A system according to embodiments may also be used to determine dehydration levels of non-human objects.

While embodiments have been discussed above using specific examples, components, and configurations, they are intended to provide a general guideline to be used for monitoring dehydration levels using RF DRO(s). These examples do not constitute a limitation on the embodiments, which may be implemented using other components, measurement schemes, and configurations using the principles described herein. Control of parameters such as level and frequency of the excitation signal for the DRO may be implemented through specific algorithms executed by computing devices.

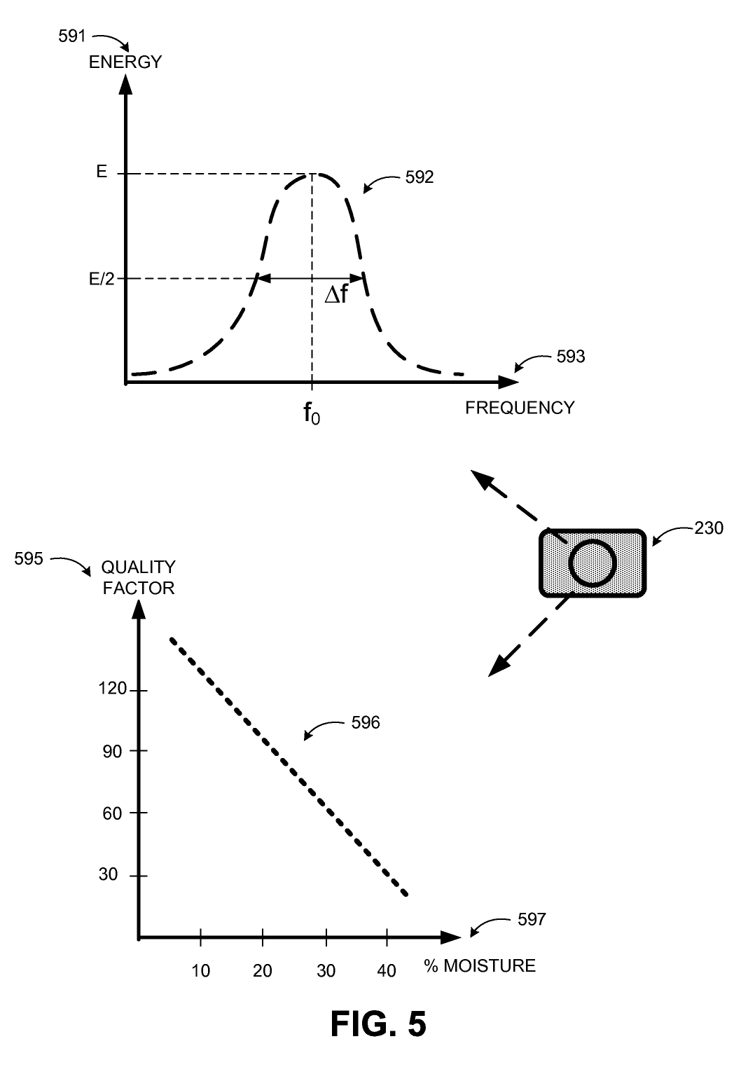

FIG. 5 includes a diagram of quality factor determination based on a frequency curve of a resonator and a diagram of a moisture vs. quality factor graph illustrating how characteristics of an RF DRO may be utilized in an RF resonator based dehydration monitoring device according to some embodiments.

As discussed in conjunction with FIG. 1, quality factor Q may be defined as a ratio of resonance frequency over bandwidth of a resonator (e.g. the resonator of sensor 230 in diagram 200). The bandwidth of a resonator may be defined as the range of frequencies where the energy stored in the resonator drops to half of its maximum value. Using the same definitions, the resonant frequency (where maximum excitation voltage occurs) may be center frequency of the band f₀. Thus, Δf in energy (591)/frequency (593) curve 592 represents the bandwidth where the energy drops from its maximum level (E) to half that amount (E/2), and the resonant frequency f₀ is the center frequency of Δf.

A system according to embodiments may sweep the frequencies of the excitation signal through the resonator of the sensor 230 comparing signal levels (and integrating to determine energy levels), then determine Δf and f₀, finally computing Q from the ratio of Δf and f₀.

At low frequencies, the relative permittivity of fluids in human body (also animals) is dominated by the high capacitance of cell membranes and the relative conductivity is dominated by ions in the blood plasma. At high frequencies, the cell membranes are shorted out and conductivity is dominated by excitation and relaxation of water molecules. The conductivity is inversely proportional to hydration levels. Thus, the hydrated the body is, the greater the high frequency conductivity. This in turn provides an approximately inverse linear relationship (596) between the quality factor 595 of the resonator and percent moisture 597 in body fluids beneath the skin. Therefore, a system according to embodiments may determine changing dehydration levels based on changing quality factor of a DRO based sensor attached to the skin.

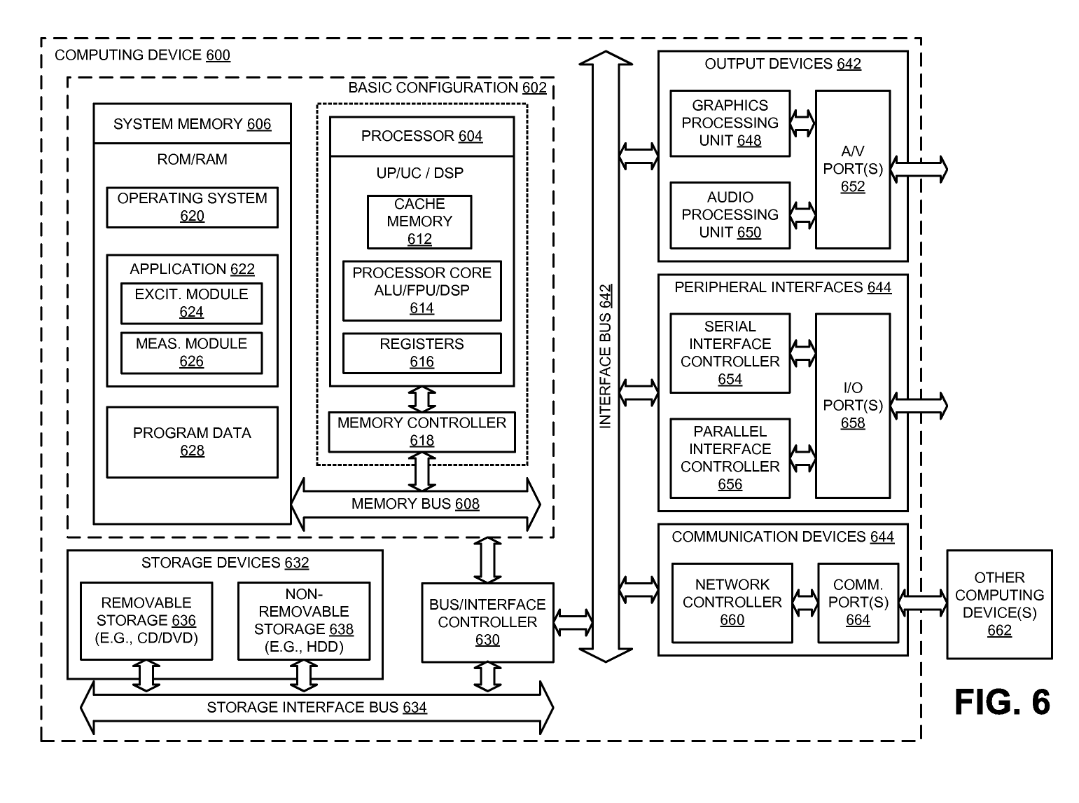

FIG. 6 illustrates a general purpose computing device 600, which may be used to monitor dehydration through a DRO device in accordance with at least some embodiments of the present disclosure. In a very basic configuration 602, computing device 600 typically includes one or more processors 604 and a system memory 606. A memory bus 608 may be used for communicating between processor 604 and system memory 606.

Depending on the desired configuration, processor 604 may be of any type including but not limited to a microprocessor (μP), a microcontroller (μC), a digital signal processor (DSP), or any combination thereof. Processor 604 may include one more levels of caching, such as a level cache memory 612, a processor core 614, and registers 616. Example processor core 614 may include an arithmetic logic unit (ALU), a floating point unit (FPU), a digital signal processing core (DSP Core), or any combination thereof. An example memory controller 618 may also be used with processor 604, or in some implementations memory controller 618 may be an internal part of processor 604.

Depending on the desired configuration, system memory 606 may be of any type including but not limited to volatile memory (such as RAM), non-volatile memory (such as ROM, flash memory, etc.) or any combination thereof. System memory 606 may include an operating system 620, one or more applications 622, and program data 628. Application 622 may include a excitation module 624 that is arranged to provide an excitation signal to an RF DRO attached to the skin of a subject and a measurement module for determining the quality factor Q and/or dielectric loss of the RF DRO according to any of the techniques discussed herein. Program data 628 may include one or more of excitation signal levels, measured Q, measured dielectric loss, and similar data as discussed above in conjunction with at least FIG. 6. This data may be useful for controlling the dehydration monitoring sensor as is described herein. In some embodiments, application 622 may be arranged to operate with program data 628 on operating system 620 as described herein. This described basic configuration 602 is illustrated in FIG. 6 by those components within the inner dashed line.

Computing device 600 may have additional features or functionality, and additional interfaces to facilitate communications between basic configuration 602 and any required devices and interfaces. For example, a bus/interface controller 630 may be used to facilitate communications between basic configuration 602 and one or more data storage devices 632 via a storage interface bus 634. Data storage devices 632 may be removable storage devices 636, non-removable storage devices 638, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 606, removable storage devices 636 and non-removable storage devices 638 are examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information and which may be accessed by computing device 600. Any such computer storage media may be part of computing device 600.

Computing device 600 may also include an interface bus 640 for facilitating communication from various interface devices (e.g., output devices 642, peripheral interfaces 644, and communication devices 646) to basic configuration 602 via bus/interface controller 630. Example output devices 642 include a graphics processing unit 648 and an audio processing unit 660, which may be configured to communicate to various external devices such as a display or speakers via one or more A/V ports 662. Example peripheral interfaces 644 include a serial interface controller 664 or a parallel interface controller 656, which may be configured to communicate with external devices such as input devices (e.g., keyboard, mouse, pen, voice input device, touch input device, etc.) or other peripheral devices (e.g., printer, scanner, etc.) via one or more I/O ports 668. The determined dehydration level may be outputted through an output device such as a display device, an audio device, and/or a printing device from the computing device 600. An example communication device 646 includes a network controller 660, which may be arranged to facilitate communications with one or more other computing devices 662 over a network communication link via one or more communication ports 664.

The network communication link may be one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR) and other wireless media. The term computer readable media as used herein may include both storage media and communication media.

Computing device 600 may be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. Computing device 600 may also be implemented as a personal computer including both laptop computer and non-laptop computer configurations. Moreover computing device 600 may be implemented as a networked system or as part of a general purpose or specialized server.

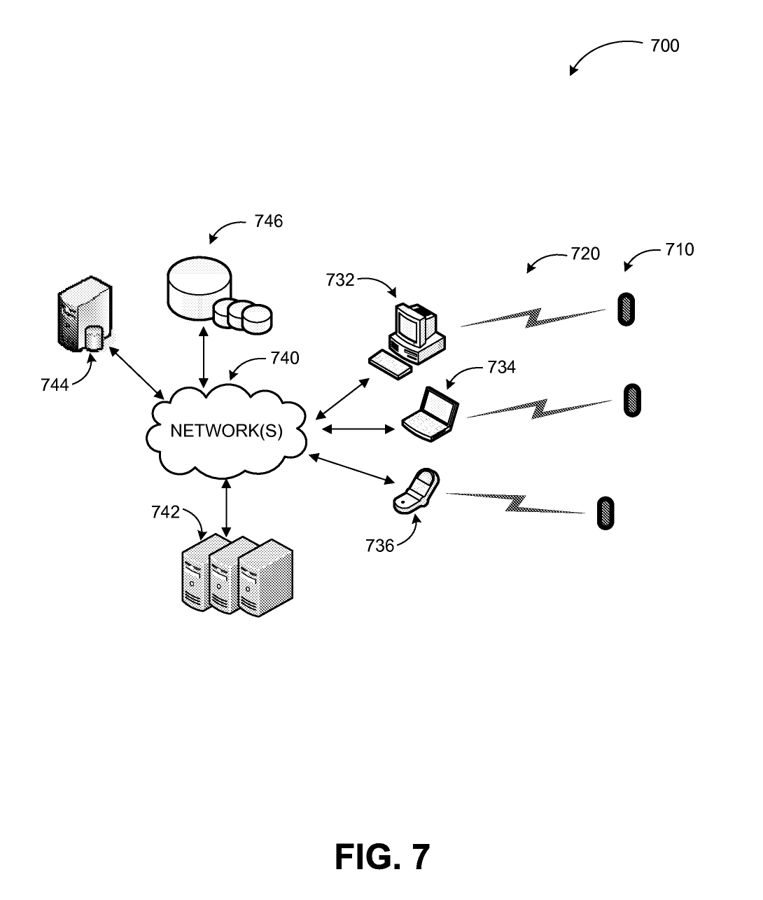

FIG. 7 illustrates a networked environment, where a system for dehydration monitoring using an RF resonator may be implemented in accordance with at least some embodiments of the present disclosure. A dehydration monitoring system based on an RF DRO attached to skin may be implemented through separate applications, one or more integrated applications, one or more centralized services, or one or more distributed services on one more computing devices. Diagram 700 illustrates an example of a distributed system implementation through networks 740.

As discussed previously, RF DROs 710 may be configured to monitor dehydration levels. RF DROs 710 may be electrically coupled to computing devices 732, 734, and 736, which may be configured to supply current to activate the resonators and determine the quality factor and/or dielectric constant of each RF DRO. Alternatively, the RF DROs may be part of a self-sufficient package that includes the excitation module and measurement module, and configured to provide feedback to the respective computing devices through direct connection of wireless connection 720. Computing device 732, 734, and 736 may be configured to determine dehydration levels and provide information associated with the dehydration levels to a monitoring service executed on one or more of servers 742. According to other embodiments, the monitoring service executed on one or more of the servers 742 may be configured to directly control the operations of the RF DROs through network(s) 740. For example, the monitoring service executed on one or more of the servers 742 may be part of a health monitoring service in a patient care facility and monitor dehydration levels of a number of patients along with other health parameters. Data associated with the dehydration level measurements and other data associated with the operation of the monitoring system (e.g., patient data) may be stored in one or more data stores such as data stores 746 and be directly accessible through network(s) 740. Alternatively, data stores 746 may be managed by a database server 744.

Network(s) 740 may comprise any topology of servers, clients, switches, routers, modems, Internet service providers (ISPs), and any appropriate communication media (e.g., wired or wireless communications). A system according to embodiments may have a static or dynamic network topology. Network(s) 740 may include a secure network such as an enterprise network (e.g., a LAN, WAN, or WLAN), an unsecure network such as a wireless open network (e.g., IEEE 802.11 wireless networks), or a world-wide network such (e.g., the Internet). Network(s) 740 may also comprise a plurality of distinct networks that are adapted to operate together. Network(s) 740 are configured to provide communication between the nodes described herein. By way of example, and not limitation, network(s) 740 may include wireless media such as acoustic, RF, infrared and other wireless media. Furthermore, network(s) 740 may be portions of the same network or separate networks.

Example embodiments may also include methods. These methods can be implemented in any number of ways, including the structures described herein. One such way is by machine operations, of devices of the type described in the present disclosure. Another optional way is for one or more of the individual operations of the methods to be performed in conjunction with one or more human operators performing some of the operations while other operations are performed by machines. These human operators need not be collocated with each other, but each can be only with a machine that performs a portion of the program. In other examples, the human interaction can be automated such as by pre-selected criteria that are machine automated.

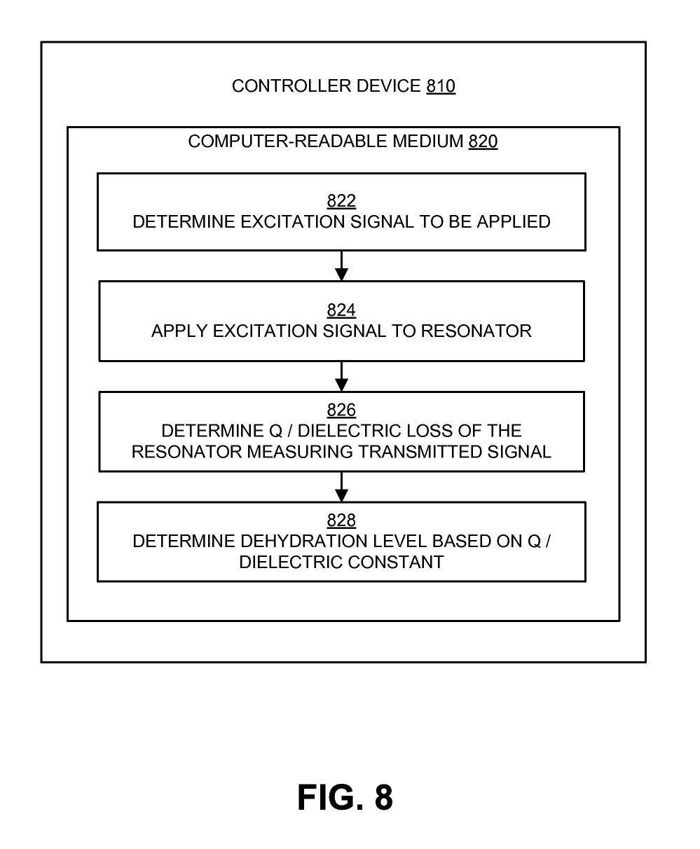

FIG. 8 illustrates a block diagram of an example computer program product, arranged in accordance with at least some embodiments described herein. Example methods described herein may be executed by a computing device, such as device 600 in FIG. 6, utilizing executable instructions and/or data that may be stored in the computer program product. In some examples, as shown in FIG. 8, computer readable medium 820 may include machine readable instructions that, when executed by, for example, controller device 810, may provide the functionality described herein such described above with respect to FIG. 1 through FIG. 3. Thus, for example, referring to controller device 810, one or more of its modules may undertake one or more of the operations shown in FIG. 8.

An example process of monitoring dehydration using an RF DRO may include one or more operations, functions or actions as is illustrated by one or more of operations 822, 824, 826 and/or 828. Some example processes may begin with operation 822, “DETERMINE EXCITATION SIGNAL TO BE APPLIED.” At operation 822, an initial RF excitation signal level and frequency may be determined by controller device 810 and control parameters may be provided from the controller device 810 to a supply source such as excitation module 236 of FIG. 2.

Operation 822 may be followed by operation 824, “APPLY EXCITATION SIGNAL TO RESONATOR.” At operation 824, the excitation module 236 may be configured to provide an RF current to the RF DRO 230 attached to the skin of a subject. As discussed previously, the dielectric constant and quality factor (Q) of the RF DRO 230 may vary based on the moisture level just below the skin such that the resonance associated with the RF DRO 230 varies as well.

Operation 824 may be followed by operation 826, “DETERMINE Q/DIELECTRIC CONSTANT OF THE RESONATOR MEASURING TRANSMITTED SIGNAL.” At operation 826, a measurement module 234 may be configured to determine the dielectric constant of the RF DRO or the quality factor, Q. For example, the energy levels are measured while the RF DRO is stimulated with a particular frequency. Then, the frequency of the stimulating signal is changed to the next scanning frequency and the energy levels measured again. After a scan of all frequencies of interest is completed, the measured energy levels may be analyzed by the measurement module 234 to identify a peak and bandwidth. Quality factor, Q, may be calculated from the determined peak and bandwidth.

Operation 826 may be followed by operation 828, “DETERMINE DEHYDRATION LEVEL BASED ON Q/DIELECTRIC CONSTANT.” At operation 826, the measurement module 234 or a computing device/processor/controller attached to the measurement module may determine absolute or relative dehydration levels based on one or more of the quality factor and/or the dielectric constant.

As discussed previously, the processors and controllers performing these operations are example illustrations and should not be construed as limitations on embodiments. The operations may also be performed by other computing devices or modules integrated into a single computing device or implemented as separate machines.

The operations included in process 800 are for illustration purposes. Monitoring dehydration using an RF DRO may be implemented by similar processes with fewer or additional operations. In some examples, the operations may be performed in a different order. In some other examples, various operations may be eliminated. In still other examples, various operations may be divided into additional operations, or combined together into fewer operations. Although illustrated as sequentially ordered operations, in some cases various operations may occur at substantially the same time, or partially overlapping in time.

There is little distinction left between hardware and software implementations of aspects of systems; the use of hardware or software is generally (but not always, in that in certain contexts the choice between hardware and software may become significant) a design choice representing cost vs. efficiency tradeoffs. There are various vehicles by which processes and/or systems and/or other technologies described herein may be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples may be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, may be equivalently implemented in integrated circuits, as one or more computer programs running on one or more computers (e.g., as one or more programs running on one or more computer systems), as one or more programs running on one or more processors (e.g. as one or more programs running on one or more microprocessors), as firmware, or as virtually any combination thereof, and that designing the circuitry and/or writing the code for the software and or firmware would be well within the skill of one of skill in the art in light of this disclosure.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein may be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors.

A typical data processing system may be implemented utilizing any suitable commercially available components, such as those typically found in data computing/communication and/or network computing/communication systems. The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermediate components. Likewise, any two components so associated may also be viewed as being “operably connected”, or “operably coupled”, to each other to achieve the desired functionality, and any two components capable of being so associated may also be viewed as being “operably couplable”, to each other to achieve the desired functionality. Specific examples of operably couplable include but are not limited to physically connectable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or, “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A method for monitoring dehydration level associated with body fluids beneath a skin using a dielectric resonator oscillator (DRO) that can be affixed to the skin, the method comprising:
applying an excitation signal to the DRO such that the DRO resonates at a particular resonance wherein the particular resonance of the DRO varies based on the dehydration level of body fluids beneath the skin;
analyzing characteristics of the excitation signal to determine a quality factor associated with the particular resonance of the DRO; and
determining the dehydration level of body fluids beneath the skin based on the quality factor associated with the particular resonance of the DRO.

2. The method according to claim 1, further comprising:
determining a frequency and a level of the excitation signal prior to applying the excitation signal.

3. The method according to claim 1, wherein analyzing the excitation signal includes:
probing an electromagnetic field generated in the DRO to detect resonant frequencies associated with the particular resonance;
sweeping the detected resonant frequencies to determine a bandwidth of the particular resonance;
determining a center frequency of the bandwidth of the particular resonance; and
computing the quality factor based on a ratio of the center frequency to the bandwidth of particular resonance.

4. The method according to claim 3, further comprising:
determining a maximum energy level associated with stored energy in the DRO;
determining two frequency values where energy stored in the DRO drops to half the value of the maximum energy level; and
determining the bandwidth of the particular resonance as a difference between the two frequency values.

5. The method according to claim 1, further comprising:
determining a conductivity of the DRO as a qualitative measure of the dehydration level.

6. The method according to claim 1, further comprising:
determining a change in conductivity of the DRO as a qualitative measure of a change in the dehydration level.

7. The method according to claim 1, further comprising:
collecting dehydration level data over a predefined period of time; and
performing one or more of formatting, analyzing, and/or reporting the collected data.

8. The method according to claim 1, further comprising:
if the determined dehydration level is above a predefined threshold, alerting one or more of a user of the sensor, a healthcare provider, and/or a designated person.

9. The method according to claim 1, further comprising:
outputting the determined dehydration level through an output device, wherein the output device corresponds to one or more of: a display device, an audio device, and a printing device.

10. A sensor that is configured to monitor a dehydration level of body fluids beneath a skin in response to a received excitation signal using a dielectric resonator oscillator (DRO) that can be affixed to the skin, the apparatus comprising:
a dielectric substrate;
a microstrip ring resonator that is supported by the dielectric substrate; and
two transmission lines that are supported by the dielectric substrate, wherein the two transmission lines are capacitively coupled to the microstrip ring resonator such that the microstrip ring resonator resonates at a particular resonance, wherein the particular resonance of the microstrip ring resonator varies based on the dehydration level of body fluids beneath the skin such that the dehydration level can be determined based on a quality factor of particular resonance of the microstrip ring resonator.

11. The sensor according to claim 10, wherein a diameter d of the microstrip ring resonator is selected based on a wavelength λ of the excitation signal according to
$$λ = \frac{π d}{N} ,$$
where N is an integer.

12. The sensor according to claim 11, wherein N is 2.

13. The sensor according to claim 12, wherein a frequency of the excitation signal is 2.4 GHz and the diameter of the microstrip ring resonator is approximately 1.3 cm.

14. The sensor according to claim 11, further comprising:
a conductive ground plane affixed to a surface of the dielectric substrate opposite another surface that supports the microstrip ring resonator and the transmission lines.

15. The sensor according to claim 11, wherein the dielectric substrate is made from a flexible material, and wherein the microstrip ring resonator and the transmission lines are metalized onto the dielectric substrate such that the sensor is flexible.

16. The sensor according to claim 11, further comprising:
a conformal coating over dielectric substrate, the microstrip ring resonator, and the transmission lines for environmental protection.

17. The sensor according to claim 11, wherein the transmission lines are electrically coupled to a measurement module, wherein the measurement module is configured to receive the excitation signal and determine the quality factor of the microstrip ring resonator.

18. A system for monitoring dehydration level of body fluids beneath a skin using a dielectric resonator oscillator (DRO) that can be affixed to the skin, the system comprising:
a sensor including a microstrip DRO and two transmission lines capacitively coupled to the microstrip DRO, wherein a particular resonance of the DRO varies based on the dehydration level of body fluids beneath the skin;
an excitation module coupled to the sensor, the excitation module adapted to provide an excitation signal to the microstrip DRO such that the DRO resonates at the particular resonance when excited by the excitation signal; and
a measurement module coupled to the sensor adapted to:
analyze characteristics of the excitation signal to determine a quality factor associated with the particular resonance of the DRO; and
determine the dehydration level of body fluids beneath the skin based on the quality factor associated with the particular resonance of the DRO.

19. The system according to claim 18, wherein the measurement module is further adapted to:
sweep resonant frequencies of the excitation signal through the microstrip DRO to determine a bandwidth of the particular resonance;
determine a center frequency of the bandwidth of particular resonance; and
compute the quality factor based on a ratio of the center frequency and the bandwidth of the particular resonance.

20. The system according to claim 18, wherein the measurement module is further adapted to:
determine a conductivity of the microstrip DRO as a qualitative measure of the dehydration level.

21. The system according to claim 18, wherein the excitation module and the measurement module are one or more of: part of a self-contained device electrically coupled to the sensor, part of a multi-component device electrically coupled to the sensor, and/or part of a computing device electrically coupled to the sensor.

22. The system according to claim 21, wherein the computing device is one of a standalone computer, a networked computer system, a micro-processor, a micro-controller, a digital signal processor, or a special purpose processing unit.

23. The system according to claim 21, wherein the self-contained device is attached to the sensor through a flexible strap such that the sensor is attachable to one of an arm, a leg, or a torso of a body.

24. The system according to claim 21, wherein the self-contained device is adapted to:
communicate through one of wireless means or electrical connection with one or more computing devices; and
provide measurement data to the one or more computing devices.

25. The system according to claim 24, wherein the one or more computing devices are adapted to:
collect dehydration level data over a predefined period of time;
one or more of: format, analyze, and/or report the collected data; and
if the determined dehydration level is above a predefined threshold, alert one or more of a user of the sensor, a healthcare provider, and/or a designated person.
